(19) United States
(12) Patent Application Publication
(10) Pub. No.: US 2021/0074497 A1
(43) Pub. Date: Mar. 11, 2021

(54) CIRCUIT PROTECTION ELEMENT

(71) Applicant: BOURNS KK, Osaka (JP)

(72) Inventor: Kohei YAMAMOTO, Osaka (JP)

(21) Appl. No.: 16/971,071

(22) PCT Filed: Feb. 14, 2019
(86) PCT No.: PCT/JP2019/005313

§ 371 Date: Aug. 19, 2020

(30) Foreign Application Priority Data
Feb. 23, 2018 (JP) 2018-031376

(51) Int. Cl. H01H 37/76

(52) U.S. Cl. CPC H01H 37/76

(57) ABSTRACT

A circuit protection element includes a vertical wall substantially perpendicular to a mounting surface of a circuit board in a mounted state; a first mounting part formed by being bent from the first end part of the vertical wall once and substantially parallel to the mounting surface; the second mounting part formed by being bent from the second end part of the vertical wall once and substantially parallel to the mounting surface; an elastic deformation part formed so as to project from the vertical wall in a predetermined direction, which has the contact part in the vicinity of an end part thereof on the opposite side to the vertical wall, and accumulates an elastic stress caused by elastic deformation thereof; and the self-locking part formed on the vertical wall and the elastic deformation part for maintaining the elastic deformation part in a state elastically deformed.

### TECHNICAL FIELD

The present invention relates to a circuit protection element mounted on a circuit board, and particularly the present invention relates to a circuit protection element that separates from the circuit board, thereby interrupting current, when the temperature near the surface of the circuit board reaches a temperature equal to or higher than the melting temperature of solder due to abnormal heat generation of an electronic component mounted on the circuit board.

### BACKGROUND ART

In Patent Document 1, a circuit protection element is proposed, which is mounted on a circuit board near an electronic component such as an IC on the circuit board, and separates from the circuit board to break and interrupt an electric current, when the electronic component abnormally generates heat due to a failure, etc., and the temperature near the surface of the circuit board reaches a temperature equal to or higher than the melting temperature of solder used to mount the element.

FIGS. 12A to 12C show a first configuration example of a circuit protection element described in Patent Document 1: FIG. 12A shows a state in which the circuit protection element 110 is formed by bending a metal plate by pressing, etc.; FIG. 12B shows a state in which the circuit protection element 110 is mounted on the circuit board 150; and FIG. 12C shows a state in which solder is melted and the circuit protection element 110 is separated from the circuit board 150. The circuit protection element 110 in a state mounted on the circuit board 150 comprises: the ceiling part 111 that is substantially parallel to a mounting surface of the circuit board 150; the first leg part 112 and the second leg part 113 that are substantially perpendicular to the mounting surface of the circuit board 150; the first mounting part 114 that is soldered to the first conductive pad 151 and second conductive pad 152 formed on the mounting surface of the circuit board 150; the second mounting part 115 that is soldered to the third conductive pad 153 formed on the mounting surface of the circuit board 150; and the contact part 116 that directly contacts the mounting surface of the circuit board 150.

As shown in FIG. 12A, the circuit protection element 110 has a relatively simple cross-sectional shape, but in a state immediately after metal processing, the first mounting part 114 and the second mounting part 115 are not flush with each other, and the first mounting part 114 is inclined with respect to the second mounting part 115. Then, as shown in FIG. 12B, the circuit protection element 110 must be mounted on the circuit board 150 so that the first mounting part 114 and the second mounting part 115 become flush with each other. At this time, an elastic deformation part formed by the ceiling part 111, the first leg part 112, and the second leg part 113 is deformed, and stress is purposely accumulated in the circuit protection element 110. Then, when the temperature near the surface of the circuit board reaches a temperature equal to or higher than the melting temperature of the solder due to abnormal heat generation by an electronic component or the like, the solder, connecting the first mounting part 114 and the second mounting part 115, respectively, to the first conductive pad 151 and second conductive pad 152 and the third conductive pad 153, is softened or melted, and the fixing of the first mounting part 114 and second mounting part 115 by soldering is released. Along with this, the stress accumulated in the circuit protection element 110 is released, the elastic deformation part of the circuit protection element 110 moves to return to the original shape, and the first mounting part 114 side jumps up, and thus the first mounting part 114 separates from the first conductive pad 151 and second conductive pad 152, and then the electric current flowing through the electric circuit between the first conductive pad 151 and the second conductive pad 152 is interrupted. As a result, the supply of electric power to the electronic component is stopped, and abnormal heat generation of the electronic component is eliminated. Although the solder fixing the second mounting part 115 to the third conductive pad 153 also melts substantially at the same time, because the contact part 116 is formed continuously with the second mounting part 115, the contact part 116 serves as a stopper to prevent the second mounting part 115 side from jumping up due to the stress accumulated inside the circuit protection element 110.

FIGS. 13A to 13C shows a second configuration example of the circuit protection element described in Patent Document 1: FIG. 13A shows a state in which a circuit protection element 120 is mounted on the circuit board 150; FIG. 13B shows a state in which the protection element 120 mounted on the circuit board 150 is deformed; and FIG. 13C shows a state in which solder is melted and the circuit protection element 130 is separated from the circuit board 150. The circuit protection element 120, in a state after being mounted on the circuit board 150 and before being deformed, comprises: the ceiling part 121 that is substantially parallel to the mounting surface of the circuit board 150; the first leg part 122 that is substantially perpendicular to the mounting surface of the circuit board 150; the second leg part 123 that is crank-shaped; the first mounting part 124 that is soldered to the first conductive pad 151 and second conductive pad 152 formed on the mounting surface of the circuit board 150; the second mounting part 125 that is soldered to the third conductive pad 153 formed on the mounting surface of the circuit board 150; and the hook part 126 that is fitted into the hole 154 formed in the mounting surface of the circuit board 150. The crank-shaped second leg part 123 further comprises: the first vertical part 123a located on a side farther from the first leg part 122; the second vertical part 123b located on a side closer to the first leg part 122; and the inclined part 123c located between the first vertical part 123a and the second vertical part 123b.

As shown in FIG. 13A, since the circuit protection element 120 of the second configuration example has no stress accumulated therein when mounted on the circuit board 150, as shown in FIG. 13B, the second leg 123 is plastically deformed by applying a force to the vicinity of the bent part 121a between the ceiling part 121 and the second leg part 123 in a direction substantially perpendicular to the mounting surface of the circuit board 150. Thereby, the ceiling part 121, the first leg part 122 and the like are elastically deformed, and stress is accumulated in those parts. Then, when the temperature near the surface of the circuit board reaches a temperature equal to or higher than the melting temperature of the solder due to abnormal heat generation of the electronic component, the solder is softened or melted in the same manner as described above, and the fixing of the first mounting part 124 with solder is released. Along with that, the stress accumulated in the circuit protection element 120 is released, and the elastically deformed part of the circuit protection element 120 moves to return to the original shape, and the first mounting part 124 side jumps up, and thus the first mounting part 124 separates from the first conductive pad 151 and the second conductive pad 152, and then the electric circuit between the first conductive pad 151 and the second conductive pad 152 is interrupted. Since the hook part 126 is fitted in the hole 154 formed in the circuit board 150 and is locked in the hole 154 by the elasticity of the hook part 126, the second mounting part 125 side is prevented from jumping up.

### PRIOR ART DOCUMENTS, PATENT DOCUMENTS

Patent Document 1: U.S. Pat. No. 8,665,057

### DISCLOSURE OF THE INVENTION

In general, when a metal plate is punched out by press-working and formed into a desired shape by being bent, and thereby its multiple different parts are made flush mutually, it is desirable to reduce the number of times of the bending. In particular, in the case of a component mounted on a portable electronic device or the like, the metal plate to be processed has a small thickness and the component itself has a very small size. Therefore, the allowable dimensional tolerance is very small, and it is substantially impossible to make a plurality of different parts flush with each other, when the number of times of the bending is 3 times or more for mass-produced elements formed by the bending and press-working.

In the circuit protection element 110 according to the first configuration example described in Patent Document 1, the first mounting part 114 and the second mounting part 115 are each formed by being bent twice with respect to the ceiling part 111 serving as a bending reference plane, however, in the state immediately after processing, the first mounting part 114 and the second mounting part 115 are not flush with each other, and the first mounting part 114 is inclined with respect to the second mounting part 115. Therefore, when the circuit protection element 110 is mounted on the circuit board 150, the first mounting part 114 must be pressed so as to be parallel to the mounting surface. Therefore, so-called reflow soldering, in which the solder paste is applied on the conductive pads in advance and the circuit board is heated, cannot be used and the manufacturing process becomes complicated. Further, in the circuit protection element 110 having a small thickness and a small size, it is difficult to keep the inclination angle of the first mounting part 114 with respect to the second mounting part 115 within allowable dimensional tolerance, and thus the variation of the stresses accumulated in the circuit protection elements 110 manufactured by mass-production becomes large. Therefore, there is a risk that the circuit protection element 110 does not function sufficiently and the current flow may not be cut off, when inclination angle of the first mounting part 114 with respect to the second mounting part 115 is small and so the stress accumulated in the circuit protection element 110 is too small.

In the circuit protection element 120 according to the second configuration example described in Patent Document 1, the first mounting part 124 is formed by being bent twice, with respect to the ceiling part 121 used as a bending reference plane, but the second mounting part 125 is formed by being bent four times. Further, even when the first vertical part 123a of the second leg part 123 is used as the bending reference plane, the first mounting part 124 and the second mounting part 125 are each formed by being bent three times. Therefore, when the circuit protection element 120 is mass-produced by press-working, it is practically impossible to make the first mounting part 124 and the second mounting part 125 flush with each other, and when the circuit protection element 120 is mounted on the circuit board 150, there is a risk that soldering failure may occur, and reflow soldering cannot be practically used.

The present invention has been made in order to solve the above-mentioned problems of the conventional example, and the object of the present invention is to provide a circuit protection element in which a plurality of mounting parts, to be mounted on a circuit board, can be formed flush with each other by being bent once with respect to a bending reference plane via processing with punching and press-working a metal plate.

In order to attain the above-mentioned subject, the circuit protection element of the present invention is formed by bending a metal plate and used on a circuit board after being mounted thereon in a state retaining an elastic stress caused by elastically deforming a part thereof after mounted so as to be used to break a circuit by releasing the elastic stress during operation, and comprises:

a vertical wall serving as a bending reference plane substantially perpendicular to a mounting surface of the circuit board in a mounted state;

a first mounting part formed by being bent from a first end part of the vertical wall once with respect to the bending reference plane and substantially parallel to the mounting surface of the circuit board;

a second mounting part formed by being bent from a second end part, different from the first end part, of the vertical wall once with respect to the bending reference plane and substantially parallel to the mounting surface of the circuit board;

an elastic deformation part formed to project from the vertical wall in a predetermined direction, which has a contact part in the vicinity of an end part thereof on an opposite side to the vertical wall and accumulates an elastic force caused by elastic deformation thereof; and a self-locking part formed on the vertical wall for maintaining the elastic deformation part in a state elastically deformed.

In the circuit protection element, the contact part of the elastic deformation part may be configured not to contact the mounting surface of the circuit board after the circuit protection element is mounted on the circuit board and before the circuit protection element is elastically deformed, and configured to contact the mounting surface of the circuit board after the circuit protection element is elastically deformed.

In the circuit protection element, the self-locking part may be configured to comprise a first engaging part formed to project from the vertical wall toward the elastic deformation part, and a second engaging part formed to project from the elastic deformation part toward the vertical wall, and configured to maintain an elastically deformed state of the elastic deformation part by engaging the first engaging part and the second engaging part mutually.

In the circuit protection element, the first mounting part and the second mounting part may be configured to face in substantially parallel to each other, and the contact part of the elastic deformation part may be configured to be located between the first mounting part and the second mounting part.

In the circuit protection element, the contact part of the elastic deformation part may be configured to be biased to one of the first mounting part and the second mounting part.

In the circuit protection element, the elastic deformation part may be configured to project from between the first end part and the second end part of the vertical wall in a direction parallel to one or both of the first mounting part and the second mounting part.

In the circuit protection element, the elastic deformation part may be configured to project from the first end part or the second end part of the vertical wall to the second mounting part or the first mounting part.

In order to attain the above-mentioned subject, the method for manufacturing the circuit protection element of the present invention comprises the steps of:

punching out a material from a metal plate, wherein the material has a bending reference plane of substantially rectangular shape, a first projecting part and a second projecting part projecting outward, respectively, from the vicinity of both ends of a first long edge of the bending reference plane of substantially rectangular shape, and a third projecting part projecting outward from the second long edge of the bending reference plane of substantially rectangular shape;

forming a first mounting part and a second mounting part, respectively, by bending the first projecting part and the second projecting part so as to be perpendicular to the bending reference plane using a line parallel to the first long edge of the bending reference plane as a predetermined folding line;

forming an elastic deformation part by bending the third projecting part a plurality of times with respect to the bending reference plane using a line parallel to the second long edge of the bending reference plane as a predetermined folding line; and

forming a self-locking part, formed on the bending reference plane or formed so as to project from the bending reference plane in a predetermined direction, for locking the elastic deformation part.

According to the above configuration, since the first mounting part and the second mounting part, which are mounted on conductive pads on a mounting surface of the circuit board when the circuit protection element is mounted on the circuit board, are formed, respectively, by bending once the metal plate with respective to the ceiling part serving as the bending reference plane, it is possible to keep the dimensional error, in the height direction of the circuit protection element with respect to the bending reference plane, within a certain allowable range, and possible to make the first mounting part and the second mounting part substantially flush with each other. Therefore, the circuit protection element can be mounted on the circuit board at the same time as mounting other electronic components by reflow soldering. And then, after the circuit protection element is mounted on the circuit board, the elastic deformation part is elastically deformed by applying a load to the elastic deformation part and pressing the part strongly toward the circuit board. At this time, the self-locking part is locked and the elastic deformation part is kept in an elastically deformed state, and elastic stress is accumulated in the circuit protection element. This state is a normal use state of the circuit protection element.

If an electronic component such as an IC mounted on the circuit board abnormally generates heat due to a failure or the like and the temperature near the surface of the circuit board reaches the melting temperature of the solder or higher, the solder, which fixes the first mounting part and the second mounting part to the conductive pads on the mounting surface of the circuit board, is softened or melted, and the fixing of the first mounting part and the second mounting part by the solder is released, and the stress accumulated in the elastic deformation part is released, and the elastic deformation part elastically deformed moves to return to its original shape. However, since the elastic deformation part and the vertical wall are locked or coupled mutually by the self-locking part, the elastic deformation part relatively presses the mounting surface of the circuit board, and the vertical wall is flipped up relatively in a direction away from the mounting surface of the circuit board. Thus, when the first mounting part or the second mounting part is completely separated from the conductive pad, the electric circuit is cut off and the power supply to electronic components is stopped.

### BRIEF DESCRIPTION OF THE DRAWINGS

FIG. 1 is a perspective view showing the circuit protection element according to the first embodiment of the present invention in a state after mounted on a circuit board but before elastically deformed.

FIG. 2 is a perspective view showing the circuit protection element according to the first embodiment in a state self-locked after elastically deformed.

FIG. 3 is a perspective view showing the circuit protection element according to the first embodiment separating from the circuit board after the temperature near the mounting surface of the circuit board rises and the solder melts.

FIGS. 4A to 4C are front views showing the circuit protection element according to the first embodiment in states mounted on a circuit board: FIG. 4A shows a state before elastically deformed; FIG. 4B shows a state self-locked after elastically deformed; and FIG. 4C shows a state in which the temperature in the vicinity of the mounting surface of the circuit board rises, the solder melts, and the circuit protection element according to the first embodiment separates from the circuit board.

FIG. 5 is a developed view of the circuit protection element according to the first embodiment.

FIG. 6 is a perspective view showing the circuit protection element according to the second embodiment of the present invention in a state after mounted on a circuit board but before elastically deformed.

FIG. 7 is a perspective view showing the circuit protection element according to the second embodiment in a state self-locked after elastically deformed.

FIG. 8 is a perspective view showing the circuit protection element according to the second embodiment separating from the circuit board after the temperature near the mounting surface of the circuit board rises and the solder melts.

FIGS. 9A to 9C are front views showing the circuit protection element according to the second embodiment in states mounted on a circuit board: FIG. 9A shows a state before elastically deformed; FIG. 9B shows a state self-locked after elastically deformed; and FIG. 9C shows a state in which the temperature in the vicinity of the mounting surface of the circuit board rises, the solder melts, and the circuit protection element according to the second embodiment separates from the circuit board.

FIG. 10 is a developed view of the circuit protection element according to the second embodiment.

FIG. 11 is a perspective view showing a modification of the circuit protection element according to the second embodiment of the present invention.

FIGS. 12A to 12C are side views showing a first configuration example of a conventional circuit protection element: FIG. 12A shows the circuit protection element in a state after bending process of a metal plate by press working etc.; FIG. 12B shows the circuit protection element in a state mounted on a circuit board; and FIG. 12C shows the circuit protection element in a state separated from the circuit board after solder is melted.

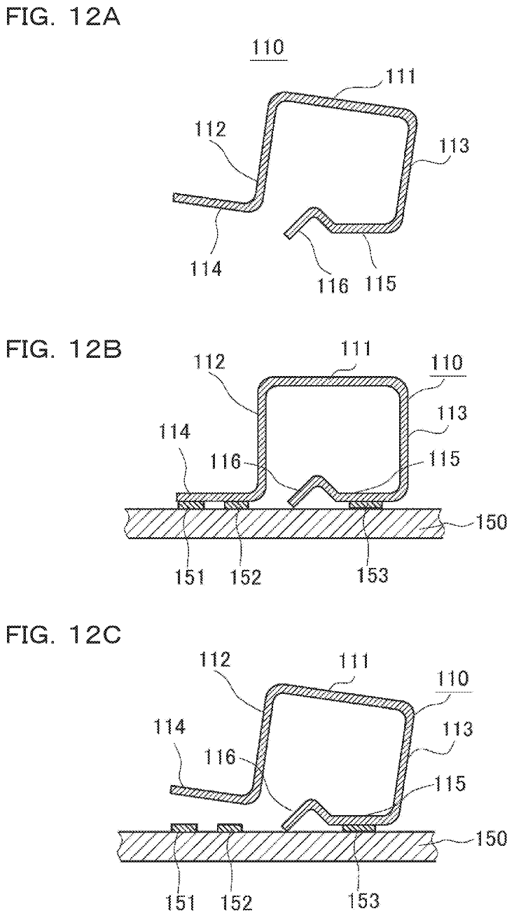

FIGS. 13A to 13C are side views showing a second configuration example of a conventional circuit protection element: FIG. 13A shows the circuit protection element in a state mounted on a circuit board; FIG. 13B shows the circuit protection element in a state deformed after mounted on the circuit board; and FIG. 13C shows the circuit protection element in a state separated from the circuit board after solder is melted.

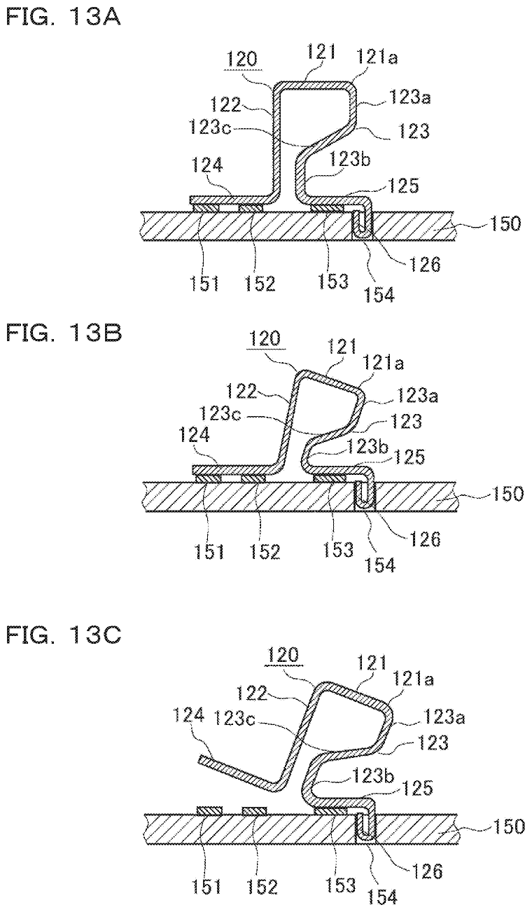

### MODE FOR CARRYING OUT THE INVENTION

The circuit protection element according to the present invention is formed by bending a metal plate and used on a circuit board in a state accumulating elastic stress in the circuit protection element by elastically deforming a part thereof after mounted on a circuit board with solder, and the circuit protection element breaks a circuit by releasing the elastic force when it operates. First, the configuration of the circuit protection element 10 according to the first embodiment of the present invention will be described.

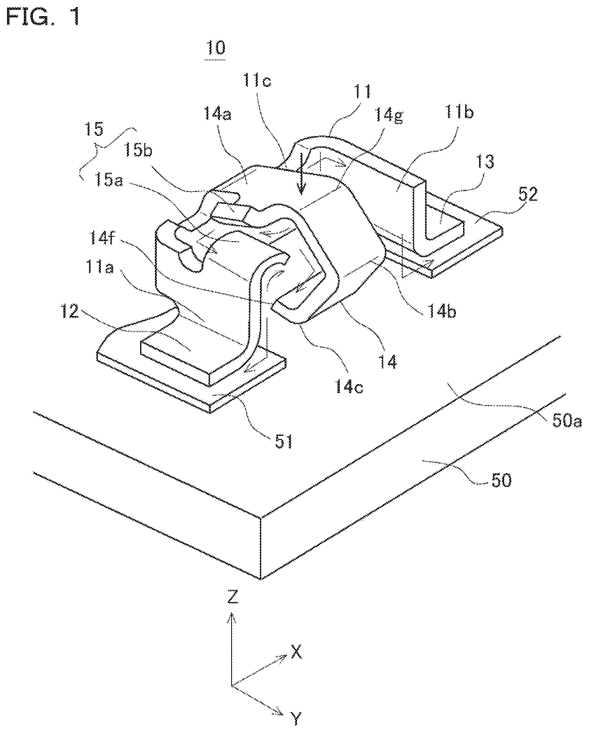

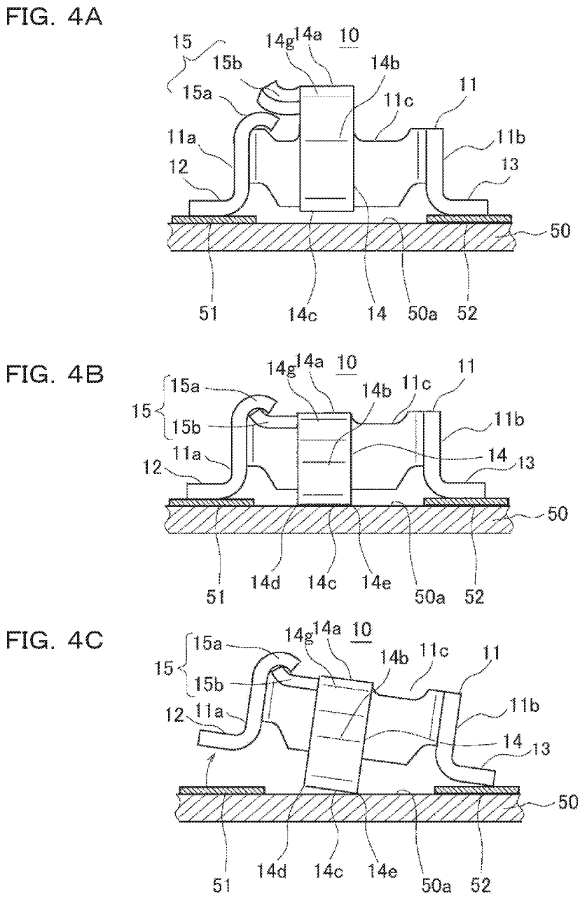

FIG. 1 and FIG. 4A show a state of the circuit protection element 10 before elastically deformed after mounted on the circuit board 50. As shown in the figures, the circuit protection element 10 comprises: the vertical wall 11 substantially perpendicular to the mounting surface 50a of the circuit board 50, having a substantially shallow U shape cross section in plan view, and serving as a bending reference plane described later; the first mounting part 12 formed by being bent once with respect to the bending reference plane from the first end part 11a of the vertical wall 11, which is substantially parallel to the mounting surface of the circuit board 50; the second mounting part 13 formed by being bent once with respect to the bending reference plane from the second end part 11b, different from the first end part 11a, of the vertical wall 11, which is substantially parallel to the mounting surface of the circuit board 50; and the elastic deformation part 14 formed so as to project in a predetermined direction from the connecting part 11c, wherein the connecting part 11c is substantially orthogonal to the first end part 11a and the second end part 11b of the vertical wall 11. Note that each of the first end part 11a, the second end part 11b, and the connection part 11c here refers to a substantially rectangular region having a fixed area. The first end part 11a and second end part 11b of the vertical wall 11 face each other substantially in parallel mutually, and also the first mounting part 12 and the second mounting part 13 that are, respectively, continuous with the first end part 11a and the second end part 11b face each other substantially in parallel. The first mounting part 12 and the second mounting part 13 are parallel to the mounting surface 50a of the circuit board 50. The elastic deformation part 14 projects in a direction parallel to the first mounting part 12 and the second mounting part 13.

The elastic deformation part 14 has a substantially J shaped cross section in a side view, and is bent at an angle slightly smaller than 90 degrees from the upper end of the connecting part 11c of the vertical wall 11 in the height direction (Z direction), and comprises the ceiling part 14a projecting slightly upward from the horizontal and the curved part 14b which is continuous with the ceiling part 14a and has a substantially V or U shaped cross section. The contact part 14c is formed in the vicinity of the free end 14f of the curved part 14b, wherein the contact part 14c contacts the mounting surface 50a of the circuit board 50 when the elastic deformation part 14 is elastically deformed. After the circuit protection element 10 is mounted on the circuit board 50 but in the state before being elastically deformed, the contact part 14c does not contact the mounting surface 50a of the circuit board 50 or the conductive pattern formed thereon, and the contact part 14c is located above the first mounting part 12 and the second mounting part 13 in the height direction. In addition, the contact part 14c of the elastic deformation part 14 (the elastic deformation part 14 itself in the first embodiment) is located closer to the first mounting part 12 side than the second mounting part 13 in the longitudinal direction. That is, the elastic deformation part 14 is formed at a position biased toward the first end part 11a side from the center of the connecting part 11c of the vertical wall 11, and as shown in FIG. 4B, the distance from the edge 14d, on the first mounting part 12 side, of the contact part 14c of the elastic deformation part 14 to the first mounting part 12 is shorter than the distance from the edge 14e, on the second mounting part 13 side, of the contact part 14c of the elastic deformation part 14 to the second mounting part 13.

Each of the vertical wall 11 and the elastic deformation part 14 is provided with the self-locking part 15 for holding the elastic deformation part 14 in an elastically deformed state. As shown in FIG. 1, in the circuit protection element 10 according to the first embodiment, the first engaging part 15a is formed from the upper end (the side opposite to the first mounting part 12) of the first end part 11a of the vertical wall 11 so as to project toward the elastic deformation part 14 side, namely, toward the inside in the longitudinal direction (X direction), and the second engaging part 15b is formed from the ceiling part 14a of the elastic deformation part 14 so as to project toward the first end part 11a side. The first engaging part 15a has a substantially arcuate cross section that is convex upward in the height direction, and the second engaging part 15b is a substantially arcuate cross section that is convex downward in the height direction.

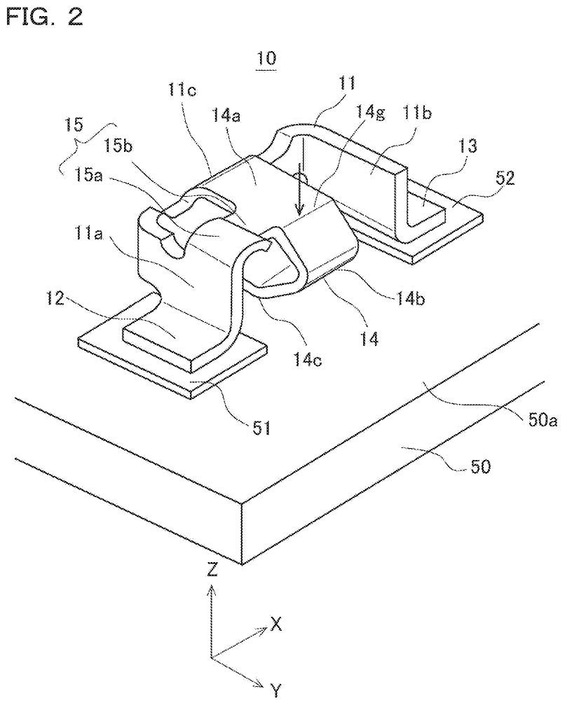

FIG. 2 and FIG. 4B each show a state of the circuit protection element 10 after mounted on the circuit board 50 and further plastically (sic) deformed. When the circuit protection element 10 is elastically deformed, a load is applied downward in the height direction in the vicinity of the connective part 14g between the ceiling part 14a and the curved part 14b of the elastic deformation part 14, and the elastic deformation part 14 is pressed, while being elastically deformed, against the mounting surface 50a side of the circuit board 50. At that time, the downward cylindrical surface of the second engaging part 15b of the self-locking part 15 slides on the upward cylindrical surface of the first engaging part 15a, and the first engaging part 15a and the second engaging part 15b pass by each other while elastically deforming, and the second engaging part 15b reaches a position closer to the mounting surface 50a of the circuit board 50 than the first engaging part 15a. When the load is released, the elastic deformation part 14 tries to return to the original shape using the elastic force thereof, however, at that time, the upward concave part of the second engaging part 15b constituting the self-locking part 15 is engaged with and locked in the downward concave part of the first engaging part 15a, and thus the elastic deformation part 14 is retained in its deformed state. As can be seen from FIG. 4A, since the dimension (or height) from the contact part 14c of the elastic deformation part 14 to the ceiling part 14a is larger than the height from the mounting surface 50a of the circuit board 50 to the downward concave part of the first engaging part 15a of the self-locking part 15, the ceiling part 14a and the curved part 14b of the elastic deformation part 14 are largely compressed, and the stress due to the elastic deformation is accumulated in the ceiling part 14a and the curved part 14b. The state shown in FIG. 2 and FIG. 4B is the normal use state of the circuit protection element 10.

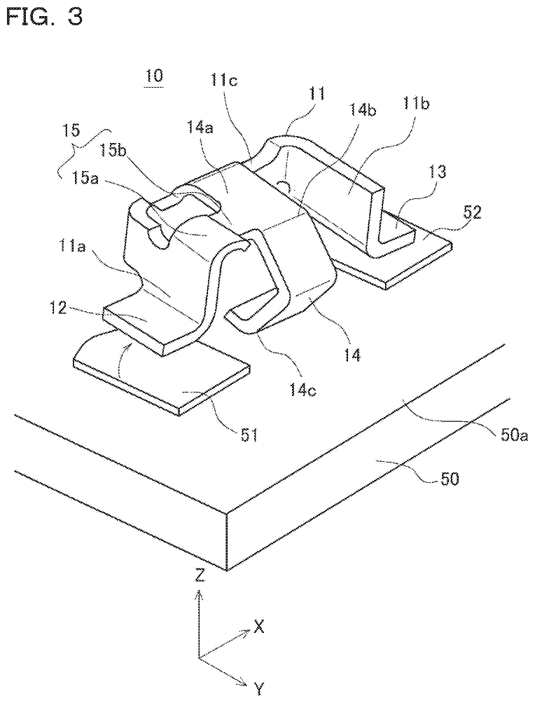

FIG. 3 and FIG. 4C show a state in which the temperature near the mounting surface 50a of the circuit board 50 rises, the solder melts, and the circuit protection element 10 separates from the circuit board 50. For example, if an electronic component (not shown) such as an IC mounted on the circuit board abnormally generates heat due to a failure or the like, and the temperature near the surface of the circuit board reaches a temperature equal to or higher than the melting temperature of the solder, the solder fixing the first mounting part 12 and the second mounting part 13 to the first conductive pad 51 and the second conductive pad 52, respectively, is softened or melted, and the fixation of the first mounting part 12 and the second mounting part 13 by soldering is released. As described above, since the elastic deformation part 14 is provided between the first mounting part 12 and the second mounting part 13 so as to be biased toward the first mounting part 12 side in the longitudinal direction, therefore, when the fixing of the first mounting part 12 and the second mounting part 13 by the solder is released; and then the elastic stress accumulated in the elastic deformation part 14 is released, the first mounting part 12, which has shorter distance to the contact part 14c of the elastic deformation part 14, is flipped up in the height direction using the edge 14e as a fulcrum which is of the contact part 14c of the elastic deformation part 14 on the second mounting part 13 side. When the first mounting part 12 is completely separated from the first conductive pad 51, the electric circuit between the first conductive pad 51 and the second conductive pad 52 is interrupted, and thus the power supply to the electronic component is stopped.

Next, a method of manufacturing the circuit protection element 10 according to the first embodiment will be described with reference to FIGS. 1 to 5. The first end part 11a and second end part 11b of the vertical wall 11, and the ceiling part 14a of the elastic deformation part 14 are each bent upward in a direction perpendicular to the paper surface. Further, in FIG. 1, thin line arrows excluding X to Z indicate bending directions. In the following description, the description of the cutout part for facilitating the bending process is omitted.

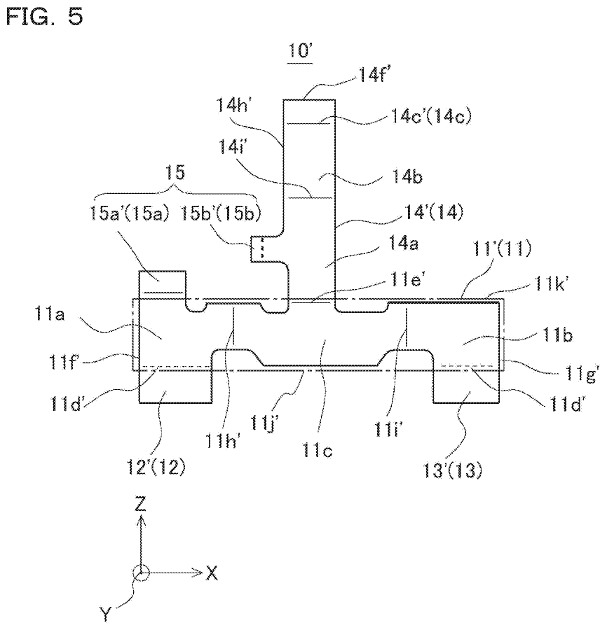

FIG. 5 shows the material 10′ of the circuit protection element 10 obtained by punching out from metal plate. The material 10′ comprises: the bending reference plane 11′ of substantially rectangular shape (corresponding to the vertical wall 11), in which the dimension in the first direction (longitudinal direction of the circuit protection element 10) is larger than the dimension in the second direction (height direction of the circuit protection element 10); the first projecting part 12′ and the second projecting part 13′ (respectively, corresponding to the first mounting part 12 and the second mounting part 13) projecting outward, respectively, from the vicinities of both ends, in the first direction, of the first long edge 11j′, in the second direction, of the bending reference plane 11′; the third projecting part 14′ (corresponding to the elastic deformation part 14) projecting outward from the vicinity of the center, in the first direction, of the second long edge 11k′, in the second direction, of the bending reference plane 11′; the fourth projecting part 15a′ projecting outward from the vicinity of one of the ends, in the first direction, of the second long edge 11k′, in the second direction, of the bending reference plane 11′; and the fifth projecting part 15b′ projecting from the edge 14h′, which is one of the two edges, in the first direction, of the third projecting part 14′, to the fourth projecting part 15a′ side.

First, the first projecting part 12′ and the second projecting part 13′ are bent, using the imaginary line 11d′ as a folding line parallel to the first long edge 11j′ of the bending reference plane 11′, by making a mountain-fold (to behind the figure) so that they are perpendicular to the bending reference plane 11′. As a result, the first mounting part 12 and the second mounting part 13 are each formed by bending once with respect to the bending reference plane 11′. In a random order, the fourth projecting part 15a′ is bent so as to be rolled inward to form the first engaging part 15a of the self-locking part 15. Also, using the imaginary lines 11h′ and 11i′ as folding lines which are inside a predetermined distance, respectively, from both end parts 11f′ and 11g′ in the first direction of the bending reference plane 11′, the first end part 11a, the second end part 11b, and the connecting part 11c are formed by making a valley-fold, to before the figure, so that they are substantially perpendicular to the bending reference plane 11′. The bending accuracy of the first end part 11a and the second end part 11b along the imaginary lines 11h′ and 11i′ only affects the parallelism between the first mounting part 12 and the second mounting part 13, and therefore it does not affect the flatness (coplanarity) of the first mounting part 12 and the second mounting part 13.

Regarding the elastic deformation part 14, the ceiling part 14a is formed by making a valley-fold, using the imaginary line 11e′ as a folding line parallel to the second long edge 11k′ of the bending reference plane 11′ so that the folding angle becomes a predetermined angle slightly smaller than 90 degrees with respect to the bending reference plane 11′. Also, the vicinity of the center of the third projecting part 14′ is bent inward in a V or U shape to form the curved part 14b using the imaginary line 14i′ as a folding line parallel to the first direction. Also, a valley-fold is made with predetermined folding angle, using the imaginary line 14c′ as a folding line which is inside a predetermined dimension from the free end 14f′ of the third projecting part 14′, so that the contact part 14c is formed on the outer peripheral surface made by the folding. Although not in any particular order, the engaging part 15b of the self-locking part 15 is formed so as to be rolled outward by bending the fifth projecting part 15b′ projecting from the third projecting part 14′ to the fourth projecting part 15a′ side in the first direction. Thereby, the circuit protection element 10 according to the first embodiment shown in FIGS. 1 and 5A (sic) is manufactured. However the elastic deformation part 14 is formed by being bent a plurality of times with respect to the reference plane 11′, since in the state after the circuit protection element 10 is mounted on the circuit board 50 and before elastically deformed, the contact part 14c of the elastic deformation part 14 does not contact the mounting surface 50a of the circuit board 50 or the conductive pattern formed thereon, and therefore the flatness, of the first mounting part 12 and the second mounting part 13 with respect to the mounting surface 50a of the circuit board 50, is not affected. Further, since the elastic deformation part 14 is bent a plurality of times so as to form the curved part 14b having a V or U shape in a cross section perpendicular to the mounting surface 50a of the circuit board 50, the contact part 14c makes line contact with the mounting surface 50 (sic) of the circuit board 50. Therefore, even though the elastic deformation part 14 is locked only at one position, namely, the first engaging part 15a formed on the ceiling part 14a, the elastic force accumulated in the elastic deformation part 14 acts uniformly on the mounting surface 50a of the circuit board 50 via the contact part 14c. Further, since the first engaging part 15a and the second engaging part 15b are formed by the bending within two times with respect to the bending reference plane 11′, the dimensional accuracy in the height direction can be within a certain tolerance range, and the self-locking function can be surely exerted.

Since the first mounting part 12 and the second mounting part 13 are simultaneously formed by being bent once with respect to the bending reference plane 11′, the reflow soldering can be performed smoothly while maintaining the first mounting part 12 and the second mounting part 13 flat. The area occupied by the circuit protection element 10 mounted on the circuit board 50 can be reduced by bending the elastic deformation part 14 inward from the connecting part 11c between the first end part 11a and second end part 11b of the vertical wall in the longitudinal direction. Further, the connecting part 11c of the vertical wall 11 is substantially perpendicular to the first mounting part 12 and the second mounting part 13, and is also substantially perpendicular to the first end part 11a and second end part 11b. Therefore, the connecting part 11c of the vertical wall 11 functions as a reinforcing part for maintaining parallelism and flatness of the first mounting part 12 and the second mounting part 13 with respect to the mounting surface 50a of the circuit board 50.

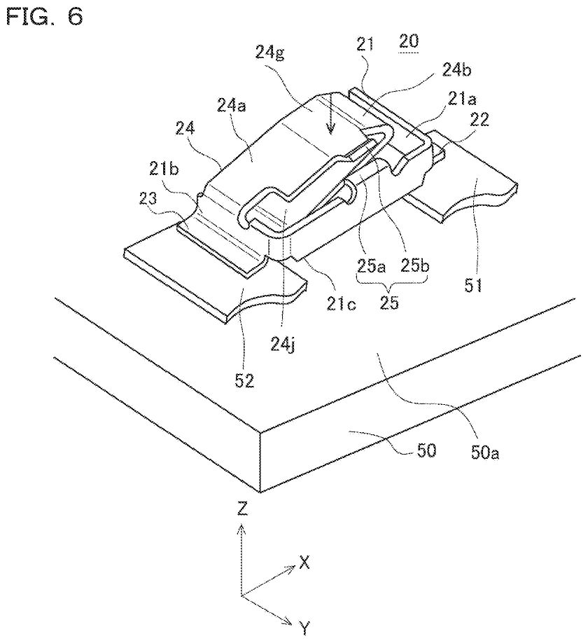

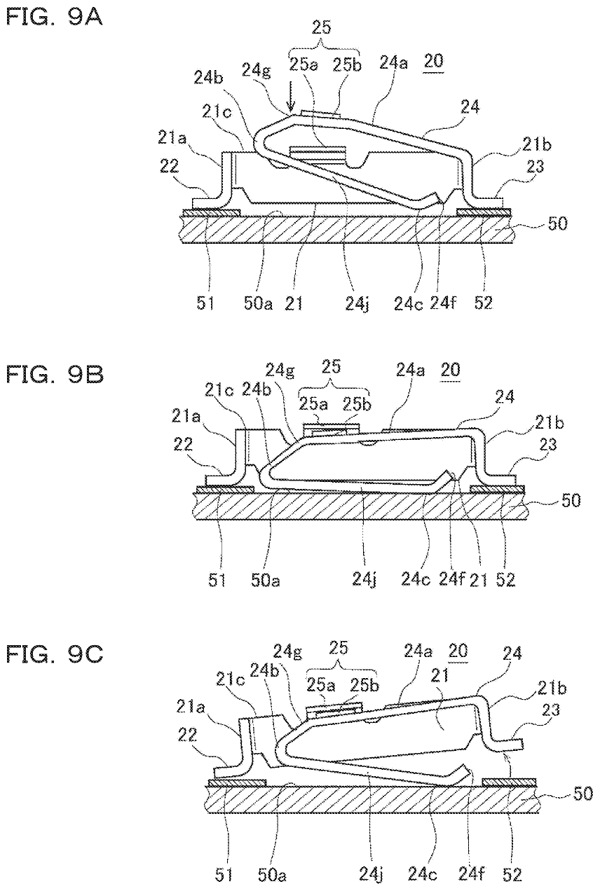

Next, the configuration of the circuit protection element 20 according to the second embodiment of the present invention will be described. FIG. 6 and FIG. 9A each show a state after the circuit protection element 20 according to the second embodiment is mounted on the circuit board 50 but before elastically deformed. As shown in the figures, the circuit protection element 20 comprises: the vertical wall 21 being substantially perpendicular to the mounting surface 50a of the circuit board 50, having a substantially shallow U shaped cross section in a plan view, and serving as a bending reference plane to be described later; the first mounting part 22 formed by being bent once from the first end part 21a of the vertical wall 21 with respect to the bending reference plane and being substantially parallel to the mounting surface of the circuit board 50; the second mounting part 23 formed by being bent once from the second end part 21b of the vertical wall 21 different from the first end part 21a of the vertical wall 21 with respect to the bending reference plane and being substantially parallel to the mounting surface of the circuit board 50; and the elastic deformation part 24 of plate spring-like formed so as to project from the second end part 21b of the vertical wall 21 in a predetermined direction substantially parallel to the connecting part 21c. As in the case of the first embodiment, each of the first end part 21a, the second end part 21b, and the connecting part 21c refers to a substantially rectangular area having a fixed area. The first end part 21a and second end part 21b of the vertical wall 21 face each other substantially in parallel mutually, and also the first mounting part 22 and the second mounting part 23, which are continuous, respectively, with the first end part 21a and the second end part 21b, face each other substantially in parallel. The first mounting part 22 and the second mounting part 23 are parallel to the mounting surface 50a of the circuit board 50. On the other hand, the elastic deformation part 24 is different from that of the first embodiment in that the elastic deformation part 24 projects in a direction substantially orthogonal to the first mounting part 22 and the second mounting part 23.

The elastic deformation part 24 has a substantially U shaped cross section in a front view, and comprises: the ceiling part 24a projecting from the upper end of the second end part 21b of the vertical wall 21 in the height direction (Z direction) slightly upward from the horizontal by being bent at an angle slightly smaller than 90 degrees; the curved part 24b continuous with the ceiling part 24a and having a substantially V or U shaped cross section; the leg part 24j extending toward the mounting surface 50a of the circuit board 50 from the curved part 24b; and others. In the vicinity of the free end 24f of the leg part 24j, the contact part 24c is formed which contacts the mounting surface 50a of the circuit board 50 when the elastic deformation part 24 is elastically deformed. In the state after the circuit protection element 20 is mounted on the circuit board 50 but before it is elastically deformed, the contact part 24c does not contact the mounting surface 50a of the circuit board 50 or the conductive pattern formed thereon, and is located above the first mounting part 22 and the second mounting part 23 in the height direction. Further, the contact part 24c (being the inflection point formed on the leg part 24j in the second embodiment) of the elastic deformation part 24 is biased toward the second mounting part 23 side with respect to the first mounting part 22 in the longitudinal direction. As shown in FIG. 9B, the distance from the contact part 24c of the elastic deformation part 24 to the first mounting part 22 is shorter (sic) than the distance from the contact part 24c to the second mounting part 23.

The vertical wall 21 and the elastic deformation part 24 are each provided with the self-locking part 25 for holding the elastic deformation part 24 in the elastically deformed state. As shown in FIG. 6, in the circuit protection element 20 according to the second embodiment, the first engaging part 25a is formed so as to project from the upper end near the central part of the connecting part 21c of the vertical wall 21 to the inside in the width direction (Y direction) to the elastic deformation part 24 side, and the second engaging part 25b is formed so as to project from the ceiling part 24a of the elastic deformation part 24 to the outside in the width direction to the connecting part 21c side of the vertical wall 21. The first engaging part 25a has a substantially arcuate cross section that is convex upward in the height direction, and the second engaging part 25b has a substantially arcuate cross section that is convex downward in the height direction.

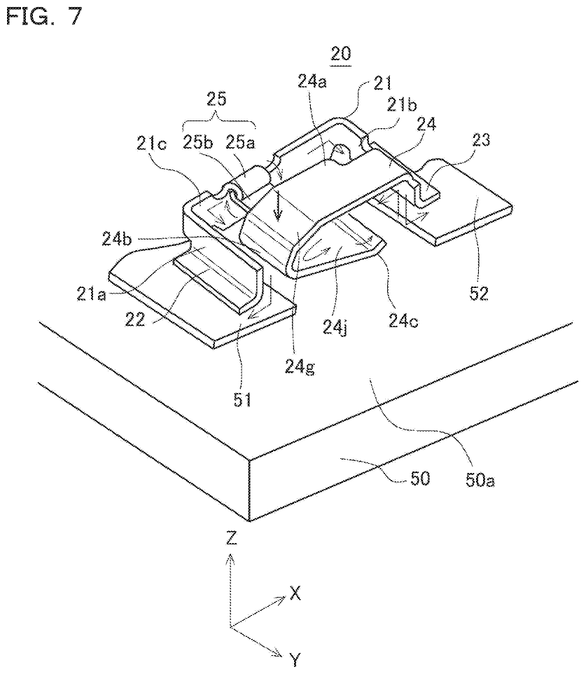

FIG. 7 and FIG. 9B each show a state after the circuit protection element 20 is mounted on the circuit board 50 and further plastically (sic) deformed. In FIG. 6 and FIG. 7, the direction in which the circuit protection element 20 is observed is changed so that the shape of the self-locking part 25 can be seen. When the circuit protection element 20 is elastically deformed, a load is applied downward in the height direction around the connective part 24g between the ceiling part 24a of the elastic deformation part 24 and the curved part 24b to press the elastic deformation part 24 against the mounting surface 50a side of the circuit board 50 while elastically deforming the elastic deformation part 24. At that time, the downward cylindrical surface of the second engaging part 25b of the self-locking part 25 slides on the upward cylindrical surface of the first engaging part 25a, so that the second engaging part 25b moves under the first engaging part 25a and reaches a position closer to the mounting surface 50a of the circuit board 50 than the first engaging part 25a while the first engaging part 25a and the second engaging part 25b respectively elastically deforming. When the load is released, the elastic deformation part 24 moves to return to the original shape due to the elastic force, however at that time the first engaging part 25a and the second engaging part 25b constituting the self-locking part 25 exert themselves so that the upward concave portion of the second engaging part 25b on the lower side is locked in the downward concave portion of the first engaging part 25a on the upper side and the elastic deformation part 24 is retained in the deformed state. As can be seen from FIG. 9A, since the dimension (or height) from the contact part 24c of the elastic deformation part 24 to the ceiling part 24a is larger than the height of the downward concave of the first engaging part 25a of the self-locking part 25 from the mounting surface 50a of the circuit board 50, the ceiling part 24a, the curved part 24b, and the leg part 24j of the elastic deformation part 24 are largely compressed, and the elastic stress due to the elastic deformation is accumulated in the ceiling part 24a, the curved part 24b, and the leg part 24j. The state shown in FIGS. 7 and 9B is the normal use state of the circuit protection element 10.

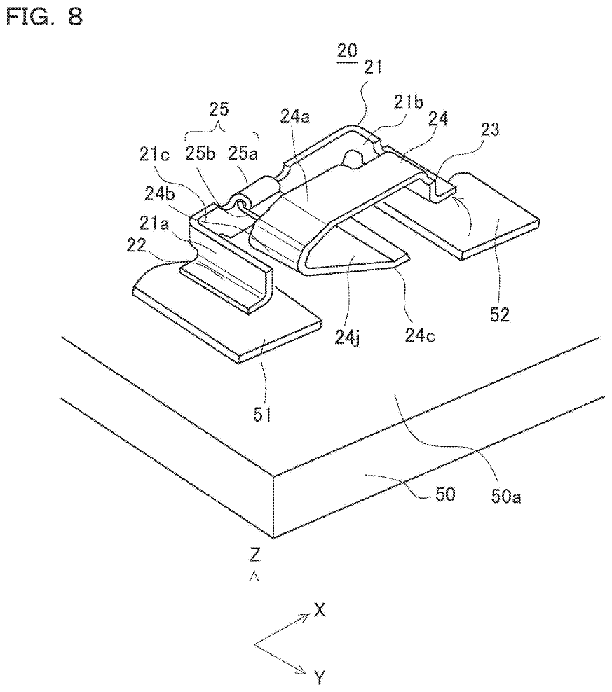

FIG. 8 and FIG. 9C each show a state in which the temperature in the vicinity of the mounting surface 50a of the circuit board 50 rises, the solder melts, and the circuit protection element 20 separates from the circuit board 50. For example, if an electronic component (not shown) such as an IC mounted on the circuit board abnormally generates heat due to a failure or the like, and the temperature near the surface of the circuit board reaches a temperature equal to or higher than the melting temperature of the solder, the solder fixing the first mounting part 22 and the second mounting part 23, respectively, to the first conductive pad 51 and the second conductive pad 52 is softened or melted, and then the fixing of the first mounting part 22 and the second mounting part 23 by the soldering is released. As described above, since the elastic deformation part 24 (sic) is provided so as to be biased toward the first mounting part 22 (sic) side between the first mounting part 22 and the second mounting part 23 in the longitudinal direction, when the fixing of the first mounting part 22 and the second mounting part 23 by the soldering is released and then the elastic stress accumulated in the elastic deformation part 24 is released, the second mounting part 23 is flipped up in the height direction by rotating around the contact part 24c of the elastic deformation part 24 used as a fulcrum. When the second mounting part 23 is completely separated from the first conductive pad 51, the electric circuit is interrupted between the first conductive pad 51 and the second conductive pad 52, and the power supply to the electronic component is stopped.

Next, a method of manufacturing the circuit protection element 20 according to the second embodiment will be described with reference to FIGS. 6 to 10. The first end part 21a and the second end part 21b of the vertical wall 21 and the ceiling part 24a of the elastic deformation part 24 are each bent upward in a direction perpendicular to the paper surface. Further, in FIG. 7, thin arrows except X to Z indicate bending directions. In the following description, the description of the cutout part for facilitating the bending process is omitted.

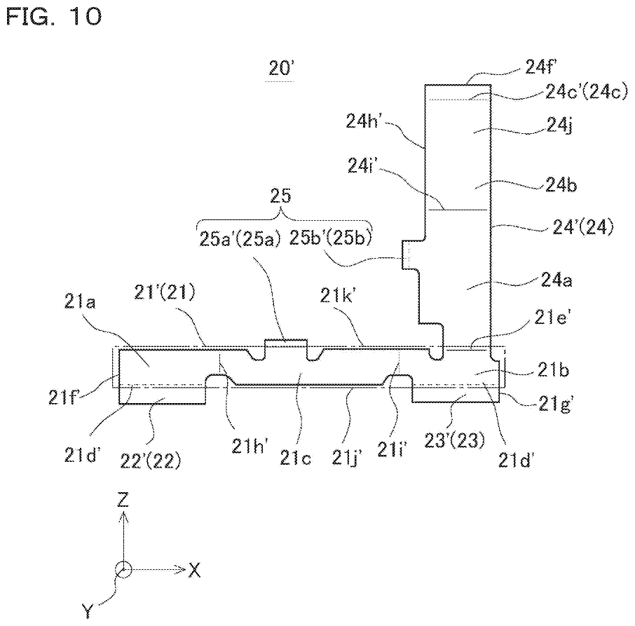

FIG. 10 shows the material 20′ of the circuit protection element 20 obtained by punching out from metal plate. The material 20′ comprises: the bending reference plane 21′ of substantially rectangular shape (corresponding to the vertical wall 21), in which the dimension in the first direction (longitudinal direction of the circuit protection element 20) is larger than the dimension in the second direction (height direction of the circuit protection element 20); the first projecting part 22′ and the second projecting part 23′ (respectively, corresponding to the first mounting part 22 and the second mounting part 23) projecting outward, respectively, from the vicinities of both ends, in the first direction, of the first long edge 21j′, in the second direction, of the bending reference plane 21′; the third projecting part 24′ (corresponding to the elastic deformation part 24) projecting outward from the vicinity of one of the ends, in the first direction, of the second long edge 21k′, in the second direction, of the bending reference plane 21′; the fourth projecting part 25a′ projecting outward from the vicinity of the center, in the first direction, of the second long edge 21k′, in the second direction, of the bending reference plane 21′; and the fifth projecting part 25b′ projecting from the edge 24h′, which is one of the two edges, in the first direction, of the third projecting part 24′, to the fourth projecting part 25a′ side.

First, the first projecting part 22′ and the second projecting part 23′ are bent, using the imaginary line 21d′ as a folding line parallel to the first long edge 21j′ of the bending reference plane 21′, by making a mountain-fold (to behind the figure) so that they are perpendicular to the bending reference plane 21′. As a result, the first mounting part 22 and the second mounting part 23 are each formed by being bent once with respect to the bending reference plane 21′. In a random order, the fourth projecting part 25a (sic) is bent so as to be rolled inward to form the first engaging part 25a of the self-locking part 25. Also, using the imaginary lines 21h′ and 21i′ as folding lines which are inside a predetermined distance, respectively, from both end parts 21f′ and 21g′ in the first direction of the bending reference plane 21′, the first end part 21a, the second end part 21b, and the connecting part 21c are formed by making a valley-fold, to before the figure, so that they are substantially perpendicular to the bending reference plane 21′. The bending accuracy of the first end part 21a and the second end part 21b along the imaginary lines 21h′ and 21i′ only affects the parallelism between the first mounting part 22 and the second mounting part 23, and therefore it does not affect the flatness (coplanarity) of the first mounting part 22 and the second mounting part 23.

Regarding the elastic deformation part 24, the ceiling part 24a is formed by making a valley-fold, using the imaginary line 21e′ as a folding line parallel to the second long edge 21k′ of the bending reference plane 21′ so that the folding angle becomes a predetermined angle slightly smaller than 90 degrees with respect to the bending reference plane 21′. Also, the vicinity of the center of the third projecting part 24′ is bent inward in a V or U shape to form the curved part 24b using the imaginary line 24i′ as a folding line parallel to the first direction. Also, a valley-fold is made with predetermined folding angle, using the imaginary line 24c′ as a folding line which is inside a predetermined dimension from the free end 24f′ of the third projecting part 24′, so that the contact part 24c is formed on the outer peripheral surface made by the folding. Although not in any particular order, the engaging part 25b of the self-locking part 25 is formed so as to be rolled outward by bending the fifth projecting part 25b′ projecting from the third projecting part 24′ to the fourth projecting part 25a′ side in the first direction. Thereby, the circuit protection element 20 according to the first embodiment shown in FIGS. 6 and 9A is manufactured. However the elastic deformation part 24 is formed by being bent a plurality of times with respect to the reference plane 21′, since in the state after the circuit protection element 20 is mounted on the circuit board 50 and before elastically deformed, the contact part 24c of the elastic deformation part 24 does not contact the mounting surface 50a of the circuit board 50 or the conductive pattern formed thereon, and therefore the flatness, of the first mounting part 22 and the second mounting part 23 with respect to the mounting surface 50a of the circuit board 50, is not affected. Further, since the elastic deformation part 24 is bent a plurality of times so as to form the curved part 24b having a U shape in a cross section perpendicular to the mounting surface 50a of the circuit board 50, the contact part 24c makes line contact with the mounting surface 50 (sic) of the circuit board 50. Therefore, even though the elastic deformation part 24 is locked only at one position, namely, the first engaging part 25a formed on the ceiling part 24a, the elastic force accumulated in the elastic deformation part 24 acts uniformly on the mounting surface 50a of the circuit board 50 via the contact part 24c. Further, since the first engaging part 15a and the second engaging part 15b are formed by the bending within two times with respect to the bending reference plane 11′, the dimensional accuracy in the height direction can be within a certain tolerance range, and the self-locking function can be surely exerted.

Since the first mounting part 22 and the second mounting part 23 are simultaneously formed by being bent once with respect to the bending reference plane 21′, the reflow soldering can be performed smoothly while maintaining the first mounting part 22 and the second mounting part 23 flat. The area occupied by the circuit protection element 20 mounted on the circuit board 50 can be reduced by bending the elastic deformation part 24 inward in the longitudinal direction from the second end part 21b of the vertical wall so as to be parallel to the connecting part 21c. Further, the connecting part 21c of the vertical wall 21 is substantially perpendicular to the first mounting part 22 and the second mounting part 23, and is also substantially perpendicular to the first end part 21a and second end part 21b. Therefore, the connecting part 21c of the vertical wall 21 functions as a reinforcing part for maintaining parallelism and flatness of the first mounting part 22 and the second mounting part 23 with respect to the mounting surface 50a of the circuit board 50.

In the case where a specific electronic component that may serve as a heat source on the circuit board 50 is known in advance and the circuit protection element 10 or 20 is mounted on such a circuit board, it is preferable that the circuit protection element 10 or 20 is arranged so that the first mounting part 12 or 22 or the second mounting part 13 or 23, being on the side closer to the contact part 14c or 24c of the elastic deformation part 14 or 24, is arranged near such a specific electronic component. In that case, according to the effect of the distance difference from the specific electronic component, a solder temperature difference occurs between two places, namely, one is close to the specific electronic component and the other is far from the specific electronic component, and the solder, fixing the mounting part and the conductive pad close to the specific electronic component, melts first. Therefore, the mounting part on the side close to the elastic deformation part 14 or 24 (sic), first separates from the conductive pad, and the current can be properly interrupted. Further, a solder, for fixing the first mounting part 12 or 22 to the first conductive pad 51 and for fixing the second mounting part 13 or 23 to the second conductive pad 52, may be of lower melting temperature, which is lower than that of the solder used for fixing other parts. The conductive pad, located far from an electronic component serving as a heat source, may be enlarged its area or its thermal capacity so that its temperature becomes lower than that of the other mounting part closer to the electronic component serving as a heat source.

In the above description, the first engaging part 15a or 25a is provided on the vertical wall 11 or 21 and also the second engaging part 15b or 25b is provided on the elastic deformation part 14 or 24, as the self-locking part 15 or 25, however the engaging part may be provided at least on the vertical wall, and such a engaging part may be configured so as to project from the vertical wall toward the elastic deformation part and to lock a part of the elastic deformation part after the elastic deformation part is deformed. Further, in the above, the first engaging part 15a or 25a and the second engaging part 15b or 25b are bent so that the sliding surfaces are cylindrical surfaces, however, the invention is not limited to such a surface, and it may be bent so as to have a swelled shape or another predetermined shape. Further, in the above description, the vertical wall 11 or 21 is bent so as to have a substantially shallow U shape cross section in a plan view, but the present invention is not limited to this, and it may be bent so as to have, for example, a substantially L shape, U shape, Z shape, and other shapes in a plan view. Further, the self-locking part is not limited to the one that requires the bending process as described above, and the self-locking part may be configured by a hole or groove formed in the vertical wall 11 or 21 and a projecting part (for which bending processing is not particularly required) projecting from the elastic deformation part 14 to the vertical wall so as to be inserted into the hole or groove.

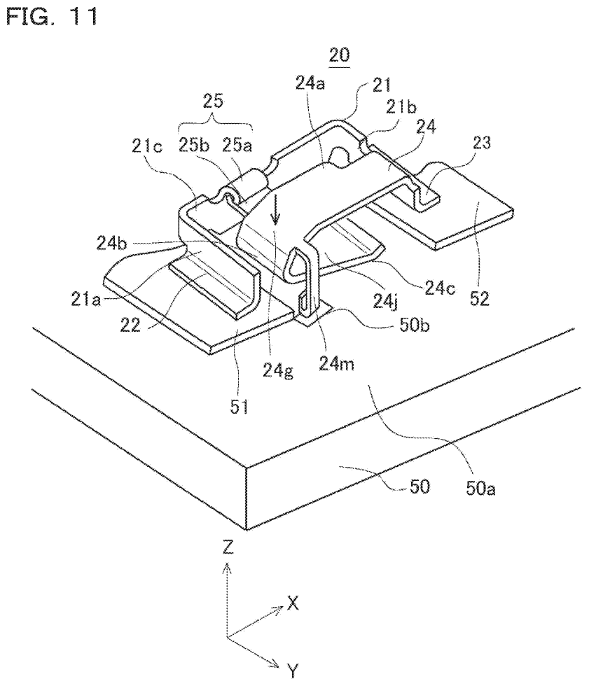

FIG. 11 shows a modification of the second embodiment. As shown in FIG. 11, in this modification, the hook part 24m is provided, projecting from the side edge portion of the elastic deformation part 24 and extending down to the mounting surface 50a of the circuit board 50, wherein the side edge portion is located at the vicinity of the boundary between the ceiling part 24a and the curved part 24b and opposite to the connecting part 21c of the vertical wall 21, and further the locking hole 50b is provided on the circuit board 50 at the position where the hook part 24m faces. When the first end part 21a side of the ceiling part 24a of the elastic deformation part 24 is strongly pressed, while being elastically deformed, against the circuit board 50, the hook part 24m of the elastic deformation part 24 goes into the locking hole 50b of the circuit board 50 and comes out and projects to the opposite side of the mounting surface of the substrate 50. When the pressing force is released, the elastic deformation part 24 tries to return to the original shape slightly by the elastic force, but at this time, the tip of the hook part 24m contacts the surface of the circuit board 50 opposite to the mounting surface 50a, and is locked. Therefore, even if the temperature near the mounting surface of the circuit board 50 rises and the solder melts, the first mounting part 22 does not separate from the conductive pad 51.

Further, the circuit protection element 20 may be configured so that a hook part similar to the above is provided near the first end part 21a of the vertical wall 21 and such a hook part is engaged with a locking hole formed on the circuit board 50 when the circuit protection element 20 is placed on the circuit board 50. As a result by such a configuration, even if the temperature near the mounting surface of the circuit board 50 rises and the solder melts, the first mounting part 22 does not separate from the conductive pad 51.

### EXPLANATIONS OF LETTERS OR NUMERALS

10, 20 circuit protection element
10′, 20′ material
11, 21 vertical wall
11a, 21a first end part (of vertical wall)
11b, 21b second end part (of vertical wall)
11c, 21c connecting part (of vertical wall)
12, 22 first mounting part
13, 23 second mounting part
14, 24 elastic deformation part
14a, 24a ceiling part
14b, 24b curved part
14c, 24c contact part
24j leg part
15, 25 self-locking part
15a, 25a first engaging part
15b, 25b second engaging part
50 circuit board
50a mounting surface

1. A circuit protection element formed by bending a metal plate and used on a circuit board after being mounted thereon in a state retaining an elastic stress caused by elastically deforming a part thereof after mounted so as to be used to break a circuit by releasing the elastic stress during operation, comprising:
a vertical wall serving as a bending reference plane substantially perpendicular to a mounting surface of the circuit board in a mounted state;
a first mounting part formed by being bent from a first end part of the vertical wall once with respect to the bending reference plane and substantially parallel to the mounting surface of the circuit board;
a second mounting part formed by being bent from a second end part, different from the first end part, of the vertical wall once with respect to the bending reference plane and substantially parallel to the mounting surface of the circuit board;
an elastic deformation part formed to project from the vertical wall in a predetermined direction, which has a contact part in the vicinity of an end part thereof on an opposite side to the vertical wall and accumulates an elastic force caused by elastic deformation thereof; and
a self-locking part formed on the vertical wall for maintaining the elastic deformation part in a state elastically deformed.

2. The circuit protection element according to claim 1, wherein the contact part of the elastic deformation part is configured not to contact the mounting surface of the circuit board at the time the circuit protection element is mounted on the circuit board and to contact the mounting surface of the circuit board after the circuit protection element is elastically deformed.

3. The circuit protection element according to claim 1, wherein the self-locking part is configured to comprise a first engaging part formed to project from the vertical wall toward the elastic deformation part, and a second engaging part formed to project from the elastic deformation part toward the vertical wall, and configured to maintain an elastically deformed state of the elastic deformation part by engaging the first engaging part and the second engaging part mutually.

4. The circuit protection element according to claim 1, wherein the first mounting part and the second mounting part are configured to face in substantially parallel to each other, and the contact part of the elastic deformation part is configured to be located between the first mounting part and the second mounting part.

5. The circuit protection element according to claim 4, wherein the contact part of the elastic deformation part is configured to be biased to one of the first mounting part and the second mounting part.

6. The circuit protection element according to claim 1, wherein the elastic deformation part is configured to project from between the first end part and the second end part of the vertical wall in a direction parallel to one or both of the first mounting part and the second mounting part.

7. The circuit protection element according to claim 1, wherein the elastic deformation part is configured to project from the first end part or the second end part of the vertical wall to the second mounting part or the first mounting part.

8. A method for manufacturing a circuit protection element, comprising the steps of:
punching out a material from a metal plate, wherein the material has a bending reference plane of substantially rectangular shape, a first projecting part and a second projecting part projecting outward, respectively, from the vicinity of both ends of a first long edge of the bending reference plane of substantially rectangular shape, and a third projecting part projecting outward from the second long edge of the bending reference plane of substantially rectangular shape;
forming a first mounting part and a second mounting part, respectively, by bending the first projecting part and the second projecting part so as to be perpendicular to the bending reference plane using a line parallel to the first long edge of the bending reference plane as a predetermined folding line;
forming an elastic deformation part by bending the third projecting part a plurality of times with respect to the bending reference plane using a line parallel to the second long edge of the bending reference plane as a predetermined folding line; and
forming a self-locking part, formed on the bending reference plane or formed so as to project from the bending reference plane in a predetermined direction, for locking the elastic deformation part.
